(19) United States
(12) Patent Application Publication
(10) Pub. No.: US 2024/0389298 A1
(43) Pub. Date: Nov. 21, 2024

(54) SEMICONDUCTOR STRUCTURE WITH MEMORY DEVICES AND METHOD FOR MANUFACTURING THE SAME

(71) Applicant: TAIWAN SEMICONDUCTOR MANUFACTURING COMPANY, LTD., Hsinchu (TW)

(72) Inventors: Chao-I WU, Hsinchu (TW); Yu-Ming LIN, Hsinchu (TW)

(73) Assignee: TAIWAN SEMICONDUCTOR MANUFACTURING COMPANY, LTD., Hsinchu (TW)

(21) Appl. No.: 18/320,464

(22) Filed: May 19, 2023

(51) Int. Cl. H10B 12/00

(52) U.S. Cl. CPC H10B 12/31; H10B 12/033; H10B 12/05; H10B 12/485

(57) ABSTRACT

A semiconductor structure includes a lower dielectric portion, a transistor in the lower dielectric portion, a support feature on the lower dielectric portion, and a capacitor. The transistor includes source, drain and gate electrodes. The support feature has an upper surface opposite to the lower dielectric portion, a lower surface confronting the lower dielectric portion, and a peripheral surface interconnecting the upper and lower surfaces. The capacitor includes: a first electrode including a bottom region beneath the lower surface, and a first surrounding region extending upwardly from an edge of the bottom region to surround the peripheral surface; a second electrode including a top region above the upper surface, and a second surrounding region extending downwardly from an edge of the top region to surround the first surrounding region; and a capacitance dielectric portion disposed to isolate the first and second electrodes from each other.

### BACKGROUND

With rapid development of semiconductor technology, critical dimension (CD) of transistors keeps shrinking. In addition, different components are often integrated together to achieve a compact and multifunctional structure. For example, embedded memories (e.g., embedded dynamic random access memory (DRAM)) can be integrated with logic transistor devices for multiple purposes. There is a continuous need for improving the structure and performance of the embedded memories.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 18 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure relates to a memory design with special fabrication processes and may be applied in all memory industries, particularly for high density memory, such as embedded dynamic random-access memory (DRAM).

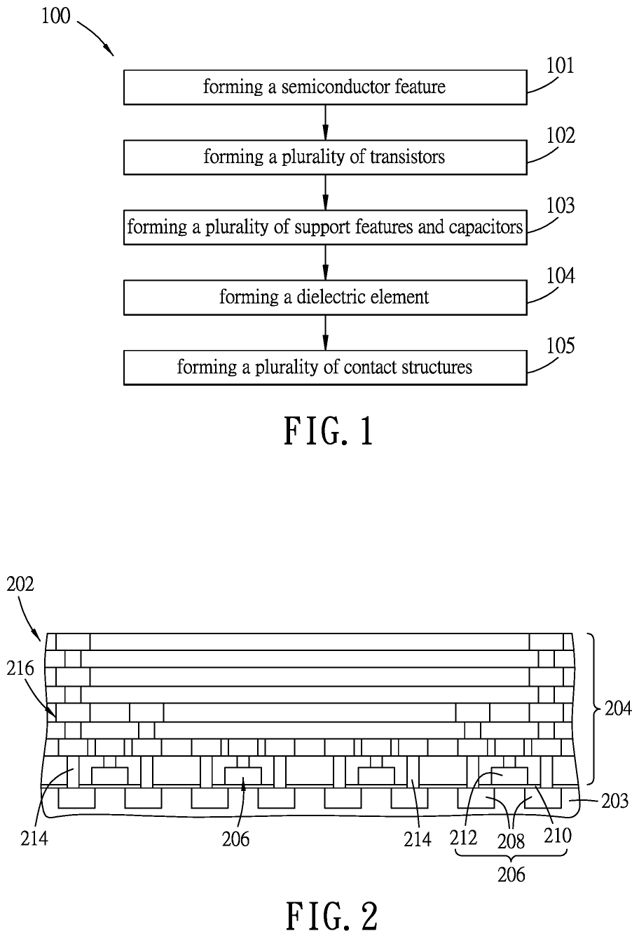

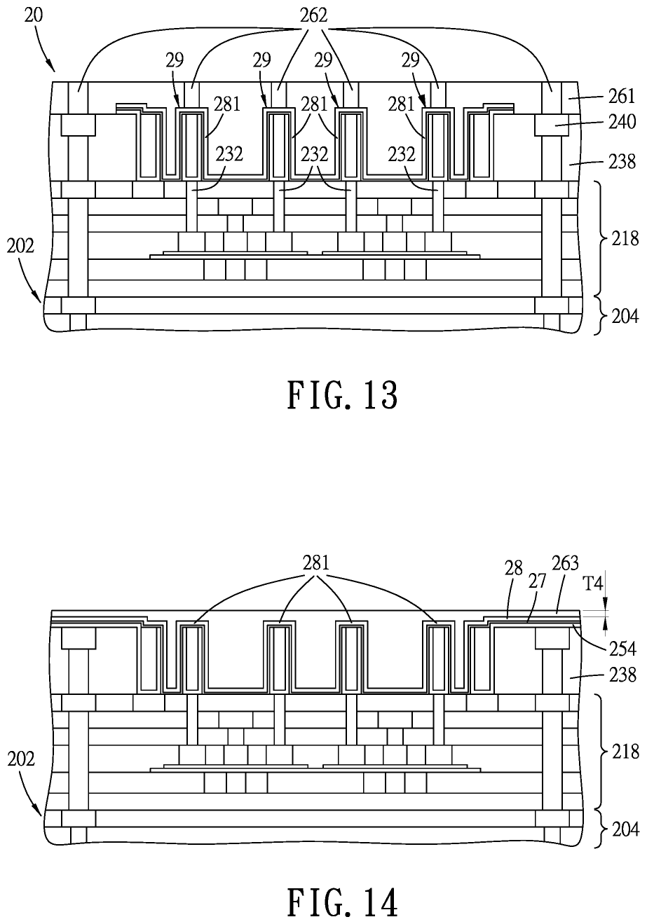

FIG. 1 is flow diagram illustrating a method 100 for manufacturing a semiconductor structure (for example, a semiconductor structure 20 shown in FIG. 13) in accordance with some embodiments. FIGS. 2 to 13 illustrate schematic views of intermediate stages of the method 100 in accordance with some embodiments. Some structures are omitted in FIGS. 2 to 13 for the sake of brevity.

Referring to FIG. 1 and the example illustrated in FIG. 2, the method 100 begins at step 101, where a semiconductor feature 202 is formed. In some embodiments, as shown in FIG. 2, the semiconductor feature 202 includes a semiconductor substrate 203, a dielectric feature 204 disposed on the semiconductor substrate 203, and a plurality of transistor features 206. Each of the transistor features 206 includes two source/drain regions 208 which are formed in the semiconductor substrate 203. In some embodiments, the source/drain regions 208 may be partially formed in the semiconductor substrate 203 and partially formed in the dielectric feature 204, or may be raised from the semiconductor substrate 203 and formed in the dielectric feature 204. In some embodiments, each of the transistor features 206 may further include a gate structure 212 which is formed in the dielectric feature 204, and a gate dielectric 210 which isolates the gate structure 212 from the source/drain regions 208. In some embodiments, the semiconductor feature 202 further includes a plurality of contacts 214 which are disposed in the dielectric feature 204, and which are respectively connected to the source/drain regions 208 of the transistor features 206. In some embodiments, the semiconductor feature 202 may further includes a back end interconnect structure 216 which is disposed in the dielectric feature 204, and which is connected to the contacts 214. In some embodiments, as schematically illustrated in FIG. 2, the dielectric feature 204 may include multiple sub-layers, and the back end interconnect structure 216 may include multiple sub-portions which are respectively disposed in the sub-layers of the dielectric feature 204. In some embodiments, the transistor features 206 may be planar metal-oxide-semiconductor field-effect transistors (MOSFETs), fin field-effect transistors (FinFETs), gate-all-around FETs (GAA FETs), nano-sheet transistors, other suitable types of device, or any combination thereof.

In some embodiments, the semiconductor substrate 203 may be made of elemental semiconductor materials, such as crystalline silicon (Si), diamond, or germanium (Ge); compound semiconductor materials, such as gallium nitride (GaN), silicon carbide (SiC), gallium arsenide (GaAs), gallium phosphide (GaP), indium arsenide (InAs), or indium phosphide (InP), indium antimonide (InSb); or alloy semiconductor materials, such as silicon germanium (SiGe), silicon germanium carbide, gallium arsenic phosphide (GaAsP), or gallium indium phosphide (GaInP). The material for forming the semiconductor substrate 203 may be doped with p-type impurities or n-type impurities, or undoped. In addition, the semiconductor substrate 203 may be a bulk silicon substrate, a silicon-on-insulator (SOI) substrate, or a germanium-on-insulator (GOI) substrate. Other suitable materials and/or configurations for the semiconductor substrate 203 (e.g., multi-layered substrates, gradient substrates, etc.) are within the contemplated scope of the present disclosure, and may be changed according to practical requirements.

In some embodiments, the source/drain regions 208 may be made by metal-organic chemical vapor deposition (MOCVD), molecular beam epitaxy (MBE), liquid phase epitaxy (LPE), vapor phase epitaxy (VPE), selective epitaxial growth (SEG), other suitable techniques, or any combination thereof, and may be made of Si, Ge, SiGe, GaAs, AlGaAs, GaAsP, SiP, SiC, SiCP, InAs, AlAs, InP, GaN, InGaAs, InAlAs, GaSb, AlSb, AlP, GaP, other suitable period III-V compound semiconductor materials, other suitable period II-VI compound semiconductor materials, other suitable materials, or any combination thereof.

In some embodiments, the gate dielectric 210 may be made of silicon oxide, silicon nitride, a high-k dielectric material, other suitable materials, or any combination thereof. In some embodiments, the high-k dielectric material may be a metal oxide or a silicate of Hf, Al, Ga, Ta, Gd, Y, Zr, La, Mg, Ba, Ti, Pb, other suitable materials, or any combination thereof. In some embodiments, the gate dielectric 210 may be formed to have any suitable thickness, and may be formed by atomic layer deposition (ALD), plasma-enhanced chemical vapor deposition (PECVD), other suitable techniques, or any combination thereof, followed by removing excess amount of the deposited materials.

In some embodiments, the gate structures 212 may be made of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, other suitable materials, or any combination thereof, and may be made by ALD, CVD, plating (including electroplating, electroless plating, etc.), other suitable techniques, or any combination thereof, followed by removing excess amount of the deposited materials.

In some embodiments, the dielectric feature 204 may be made of SiO₂, SiOCH, borophosphosilicate glass (BPSG), undoped silicate glass (USG), fluorinated silicate glass (FSG), high-density plasma (HDP) oxide, other suitable materials, or any combination thereof, and may be formed by ALD, CVD, physical vapor deposition (PVD), other suitable techniques, or any combination thereof, followed by removing excess amount of the deposited materials.

In some embodiments, the contacts 214 may be made of W, Ru, Al, Mo, Ti, TiN, TiSi, CoSi, NiSi, Cu, TaN, Co, other suitable materials, or any combination thereof, and may be made by CVD, ALD, PVD, plating (including electroplating, electroless plating, etc.), other suitable techniques, or any combination thereof, followed by removing excess amount of the deposited materials.

In some embodiments, the back end interconnect structure 216 may be made of a metal or metal-containing material such as Cu, W, Co, Ru, Ti, TiN, Ta, TaN, Mo, Ni, Pt, a low resistivity metal constituent, other suitable materials, alloys thereof, or combinations thereof, and may be made by CVD, ALD, PVD, plating (including electroplating, electroless plating, etc.), other suitable techniques, or any combination thereof, followed by removing excess amount of the deposited materials.

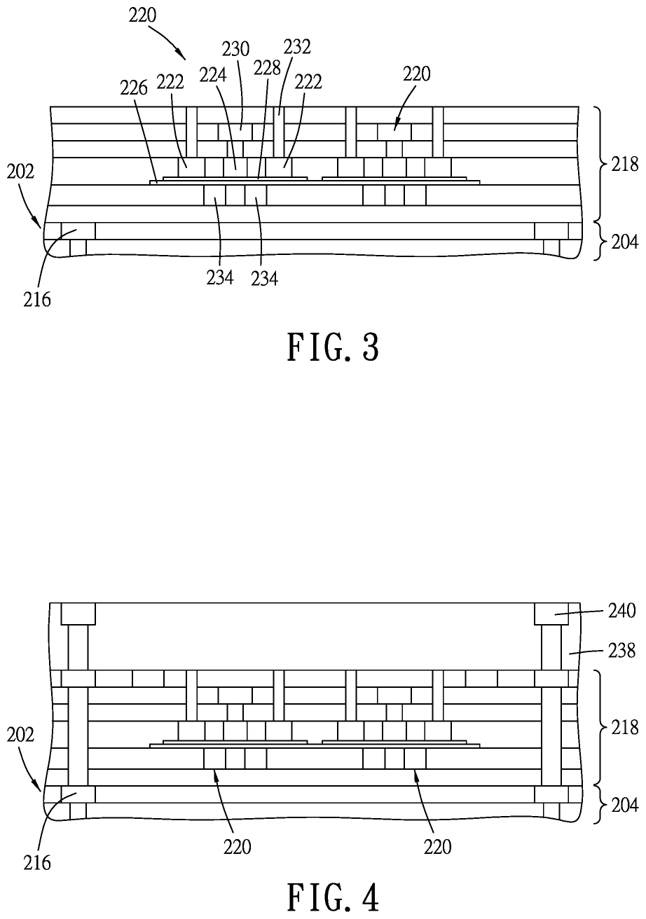

Referring to FIG. 1 and the example illustrated in FIG. 3, the method 100 proceeds to step 102, where a plurality of transistors 220 are formed. FIG. 3 is a view illustrating the structure after step 101, where only a top portion of the semiconductor feature 202 is shown in FIG. 3.

As shown in FIG. 3, in some embodiments, prior to the formation of the transistors 220, a lower dielectric portion 218 may be formed on the dielectric feature 204, followed by forming the transistors 220 in the lower dielectric portion 218. In some embodiments, each of the transistors 220 includes a gate dielectric layer 226, a channel layer 228 disposed on the gate dielectric layer 226, at least one source electrode 222 disposed on the channel layer 228, at least one drain electrode 224 disposed on the channel layer 228, and at least one gate electrode 234 (may be referred to as back gate 234 in some embodiments) disposed on the gate dielectric layer 226 opposite to the channel layer 228. In some embodiments, each of the transistors 220 may include one drain electrode 224 and two source electrodes 222 as shown in FIG. 3, and the numbers of the source and drain electrodes 222, 224 may be changed according to practical requirements. In some embodiments, each of the transistors 220 may include two gate electrodes 234, and the number of the gate electrode(s) 234 may be changed according to practical requirements. In some embodiments, each of the transistors 220 may further include a bit line 230 which is formed in the lower dielectric portion 218 and which is electrically connected to one of the source and drain electrodes 222, 224. In the embodiment shown in FIG. 3, the bit line 230 is connected to the drain electrode 224. In some embodiments, each of the transistors 220 may further include a via contact 232 which is formed in the lower dielectric portion 218 and which is electrically connected to the other one of the source and drain electrodes 222, 224. In the embodiment shown in FIG. 3, each of the transistors 220 includes two via contacts 232 which are respectively connected to the source electrodes 222. The number of the transistors 220 may be changed according to practical requirements. In some embodiments, as schematically illustrated in FIG. 3, the lower dielectric portion 218 may include multiple sub-layers, according to practical requirements.

In some embodiments, the lower dielectric portion 218 may be made of a dielectric material similar to those for forming the dielectric feature 204. In some embodiments, the gate electrodes 234 may be made of silver (Ag), aluminum (Al), copper (Cu), tungsten (W), nickel (Ni), metal-containing nitrides (e.g., titanium nitride (TiN), tantalum nitride (TaN), etc.), metal-containing silicides (e.g., NiSi, etc.), metal-containing carbides (e.g., TaC, etc.), other suitable materials, or any combination thereof. In some embodiments, the gate electrodes 234 may be made of a material similar to those for forming the gate structures 212 of the transistor features 206. In some embodiments, the gate dielectric layer 226 may be made of a dielectric material similar to those for forming the gate dielectrics 210 of the transistor features 206. In some embodiments, the channel layer 228 may be made of indium gallium zinc oxide (IGZO), indium zinc oxide (IZO), zinc oxide (ZnO), indium tin oxide (InSnO), tungsten-doped indium oxide (InWO), gallium oxide (GaOₓ), indium oxide (InOₓ), other suitable materials, or any combination thereof. In some embodiments, the source and drain electrodes 222, 224, the bit line 230, and the via contacts 232 may be made of an electrically conductive material similar to those for forming the gate electrodes 234, the gate structures 212, or the back end interconnect structure 216.

Referring to FIG. 1 and the example illustrated in FIGS. 4 to 11, the method 100 proceeds to step 103, where a plurality of support features 258 and capacitors 29 are formed.

In some embodiments, step 103 may include sub-steps 1021 to 1027.

Referring to FIG. 4, which is a view illustrating the structure after step 102, in sub-step 1021, a dielectric structure 238 is formed to be disposed on the lower dielectric portion 218, followed by forming an upper interconnect structure 240 which extends through the dielectric structure 238 and the lower dielectric portion 218 so as to be electrically connected to the back end interconnect structure 216 of the semiconductor feature 202. In some embodiments, as shown in FIG. 4, the upper interconnect structure 240 may include multiple sub-portions which are disposed in the lower dielectric portion 218 and the dielectric structure 238, and the number of the sub-portions may be changed according to practical requirements. In some embodiments, the dielectric structure 238 may be made of a dielectric material similar to those for forming the lower dielectric portion 218. In some embodiments, the upper interconnect structure 240 may be made of an electrically conductive material similar to those for forming the back end interconnect structure 216.

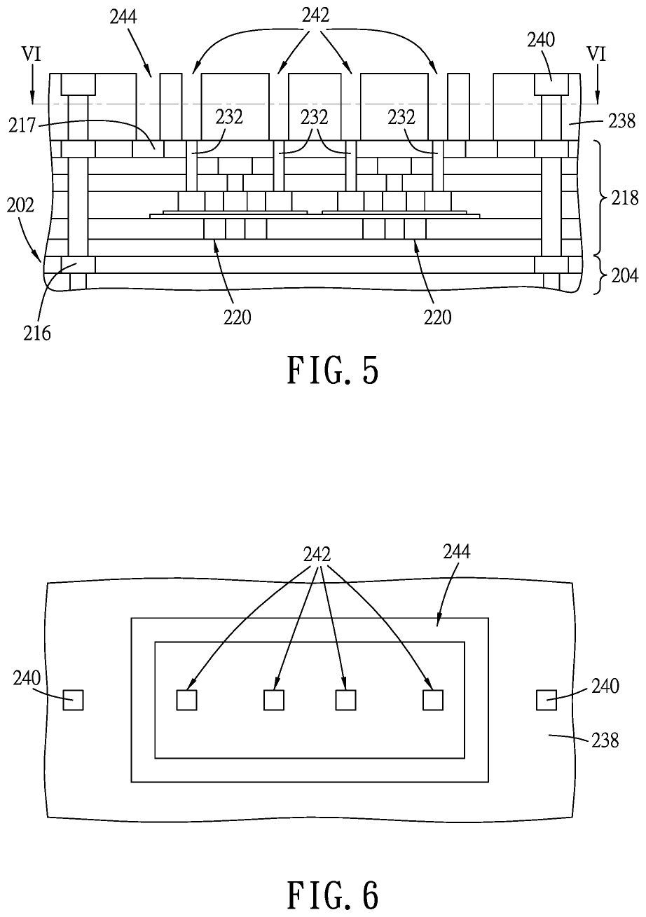

FIG. 5 is a view illustrating the structure after the step for making the structure shown in FIG. 4, and FIG. 6 is a top view taken from line VI-VI of FIG. 5. Referring to FIGS. 5 and 6, in sub-step 1022, a plurality of spaced-apart openings 242 are formed in the dielectric structure 238 by dry etch, wet etch, other suitable techniques, or any combination thereof. The number, dimension and aspect ratio of each of the openings 242 may be determined according to practical requirements. In some embodiments, the via contacts 232 are respectively exposed from the openings 242; in other embodiments, some of the via contacts 232 are exposed from the openings 242, while the other of the via contacts 232 are not exposed. In some embodiments, in addition to the formation of the openings 242, a trench 244 is formed in the dielectric structure 238 to surround the openings 242. In some embodiments, the trench 244 may be formed by a technique similar to those for forming the openings 242. The dimension of the trench 244 may be changed according to practical requirements. In some embodiments, the openings 242 may be formed prior to forming the trench 244, the trench 244 may be formed prior to forming the openings 242, or the openings 242 and the trench 244 may be formed simultaneously. In other embodiments, some of the openings 242 may be first formed, followed by simultaneously forming the remaining openings 242 and the trench 244.

In some embodiments, a metal pattern 217 formed in the lower dielectric portion 218 may serve as a stop layer during forming of the trench 244. The metal pattern 217 may be made of a material similar to those for forming the via contacts 232.

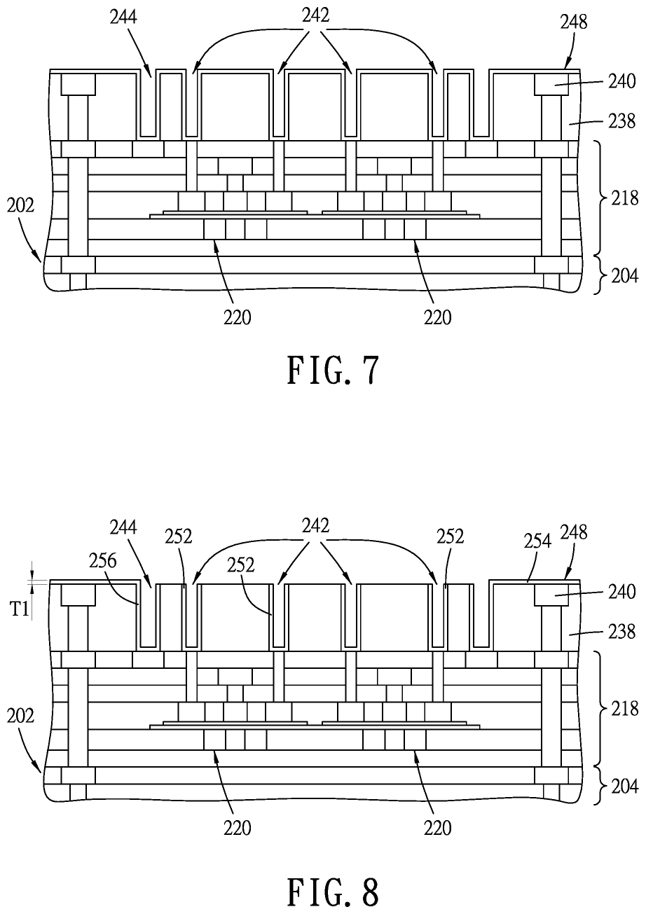

FIG. 7 is a view illustrating the structure after the step for making the structure shown in FIG. 5. Referring to FIG. 7, in sub-step 1023, an electrode layer 248 is formed on the dielectric structure 238, and is formed in the openings 242 and the trench 244, where the openings 242 and the trench 244 are only partially filled by the electrode layer 248. Then, referring to FIG. 8, portions of the electrode layer 248 in FIG. 7 are removed to form a plurality of first electrodes 252 respectively in the openings 242 and a third electrode 256 in the trench 244 (i.e., the first and third electrodes 252, 256 are simultaneously formed). In some embodiments, the electrode layer 248 may be formed by PVD, CVD, ALD, other suitable techniques, or any combination thereof. In some embodiments, the electrode layer 248 may be formed in a conformal manner on the dielectric structure 238 and the upper interconnect structure 240, and in the openings 242 and the trench 244. In some embodiments, the portions of the electrode layer 248 may be removed by plasma dry etch, wet etch, other suitable techniques, or any combination thereof. In some embodiments, the remaining electrode layer 248 includes the first electrodes 252, the third electrode 256, and a protective portion 254 covering the upper interconnect structure 240. In some embodiments, the electrode layer 248 (i.e., the first electrodes 252 and the third electrode 256) may be made of an electrically conductive material similar to those for forming the back end interconnect structure 216. In some embodiments, the electrode layer 248 may have a thickness (T1) which ranges from about 3 nm to about 15 nm and which may be varied according to practical requirements. In some embodiments, each of the first and third electrodes 252, 256 has a U-shaped cross-section.

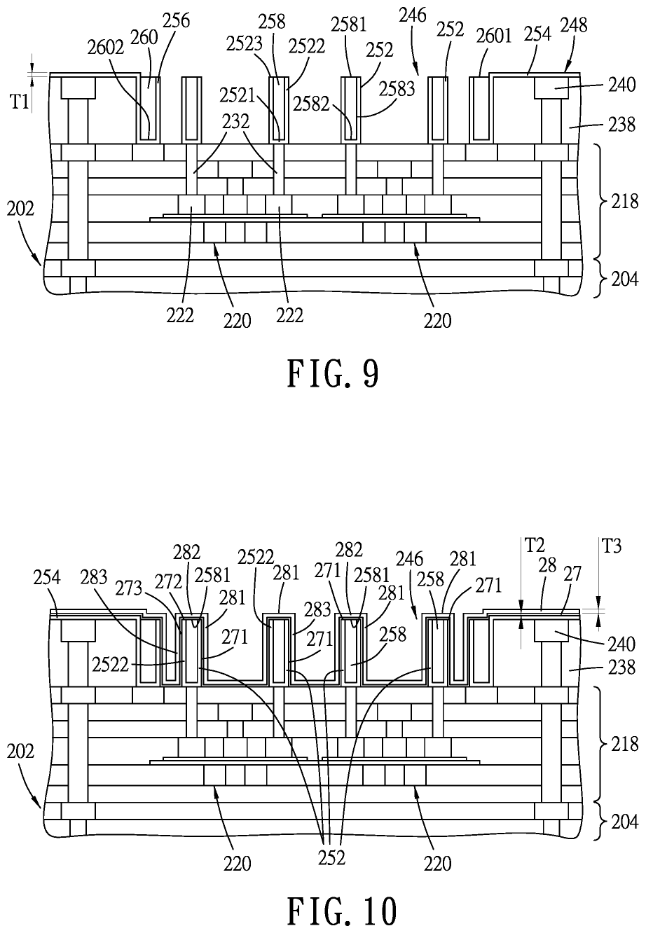

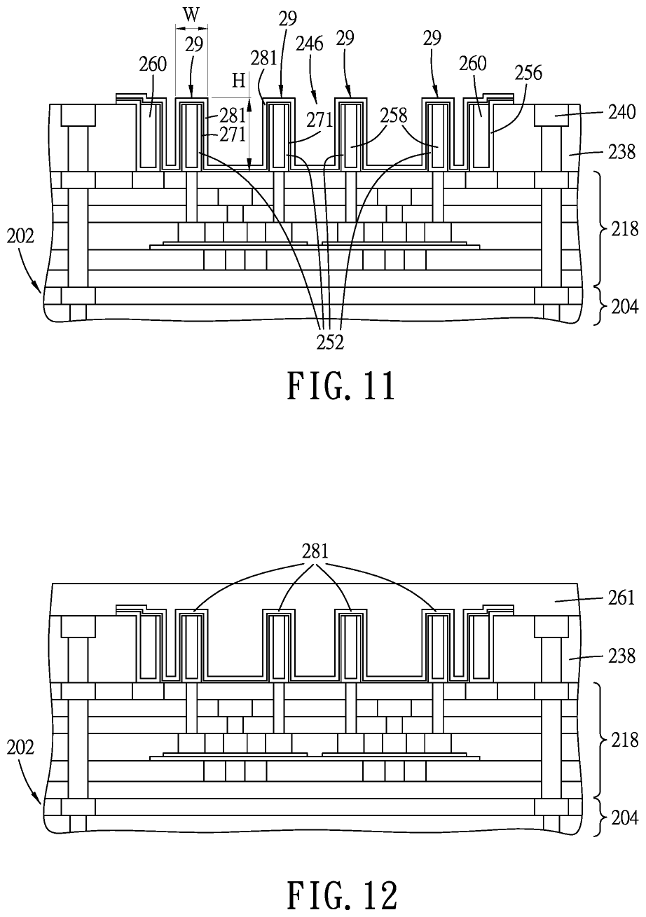

FIG. 9 is a view illustrating the structure after the step for making the structure shown in FIG. 8. Referring to FIG. 9, in sub-step 1024, a plurality of support features 258 are respectively formed in the openings 242 (see also FIG. 8) and on the first electrodes 252, and an isolation feature 260 is formed in the trench 244 (see also FIG. 8) over the third electrode 256. That is, each of the openings 242 shown in FIGS. 5 and 6 is completely filled by a corresponding one of the first electrodes 252 and a corresponding one of the support features 258, and the trench 244 shown in FIGS. 5 and 6 is completely filled by the third electrode 256 and the isolation feature 260. In some embodiments, the support features 258 may be made of an electrically conductive material similar to those for forming the first electrodes 252, a dielectric material similar to those for forming the dielectric structure 238, a high-k dielectric material, or other suitable materials. The isolation feature 260 may be made of the material the same as or different from that of the support features 258. In some embodiments, the support features 258 and the isolation feature 260 are formed simultaneously, and may be formed by ALD, CVD, PVD, other suitable techniques, or any combination thereof, followed by removing excess amount of the deposited materials. In the case that the isolation feature 260 is made of a dielectric material, the capacitors 29 (see FIG. 11) can be effectively isolated from the upper interconnect structure 240 and the dielectric structure 238 which remain after sub-step 1027. The materials for making the support features 258 and the isolation feature 260 may be changed according to practical requirements, and are not limited to those described above.

In some embodiments, the support features 258 are disposed on the lower dielectric portion 218 and surrounded by the first electrodes 252, respectively. Each of the support features 258 has an upper surface 2581 opposite to the lower dielectric portion 218, a lower surface 2582 confronting the lower dielectric portion 218, and a peripheral surface 2583 interconnecting the upper and lower surfaces 2581, 2582.

In some embodiments, each of the first electrodes 252 includes a bottom region 2521 and a first surrounding region 2522. The bottom region 2521 is disposed beneath the lower surface 2582 of a corresponding one of the support features 258, and the first surrounding region 2522 extends upwardly from an edge of the bottom region 2521 to surround the peripheral surface 2583 of the corresponding support feature 258.

In some embodiments, the isolation feature 260 is surrounded by the third electrode 256, and includes a first surface 2601 opposite to the lower dielectric portion 218, and a second surface 2602 confronting the lower dielectric portion 218. The first surrounding region 2522 of each of the first electrodes 252 includes a top surface 2523. The upper surfaces 2581 of the support features 258, the top surfaces 2523 of the first electrodes 252, and the first surface 2601 of the isolation feature 260 are flush with each other.

In some embodiments, the via contacts 232 respectively extend downwardly from the bottom regions 2521 of the first electrodes 252 so as to be electrically connected to the source electrodes 222 of the transistors 220.

Referring further to FIG. 9, in sub-step 1025, a portion of the dielectric structure 238, which is surrounded by the third electrode 256 and which is disposed among the first and third electrodes 252, 256, is removed to form a recess 246. In some embodiments, sub-step 1025 is performed by dry etch, wet etch, other suitable techniques, or any combination thereof.

FIG. 10 is a view illustrating the structure after the step for making the structure shown in FIG. 9. Referring to FIG. 10, in sub-step 1026, a capacitance dielectric layer 27 and a layer 28 including a plurality of second electrodes 281 are sequentially formed over the structure obtained in sub-step 1025 using ALD, CVD, PVD, other suitable techniques, or any combination thereof. In some embodiments, at least one of the capacitance dielectric layer 27 and the layer 28 may be deposited in a conformal manner; and, in other embankments, both the capacitance dielectric layer 27 and the layer 28 are deposited in a conformal manner. In some embodiments, the capacitance dielectric layer 27 is made of hafnium oxide (e.g., HfO₂), zirconium oxide (e.g., ZrO₂), zirconium aluminum oxide (ZrAlOₓ), hafnium aluminum oxide (HfAlOₓ), hafnium silicon oxide (HfSiOₓ), aluminum oxide (e.g., Al₂O₃), or other suitable materials. Possible materials for forming the layer 28 may be similar to those for forming the first electrodes 252. In some embodiments, the layer 28 is made of a material the same as or different from that of the first electrodes 252 according to practical requirements.

In some embodiments, the capacitance dielectric layer 27 includes a plurality of capacitance dielectric portions 271, each of which covers one of the first electrodes 252 and a corresponding one of the support features 258. In some embodiments, the capacitance dielectric layer 27 has a thickness (T2) which ranges from about 1 nm to about 10 nm and which may be varied according to practical requirements.

In some embodiments, the layer 28 has a thickness (T3) which ranges from about 3 nm to about 15 nm, and which may be varied according to practical requirements. In some embodiments, each of the second electrodes 281 includes a top region 282 and a second surrounding region 283. The top region 282 is disposed above the upper surface 2581 of a corresponding one of the support features 258 and above the top surface 2523 of a corresponding one of the first electrodes 252. The second surrounding region 283 extends downwardly from an edge of the top region 282 to surround the first surrounding region 2522 of the corresponding one of the first electrodes 252. The second electrodes 281 are isolated and separated from the first electrodes 252 through the capacitance dielectric portions 271, respectively. In some embodiments, the lower surface 2582 of each of the support features 258 is directly connected to the bottom region 2521 of a corresponding one of the first electrodes 252, and the upper surface 2581 of each of the support features 258 is directly connected to a corresponding one of the capacitance dielectric portions 271.

In some embodiments, each of the capacitance dielectric portions 271 includes a first region 272 and a second region 273. The first region 272 is disposed between the top region 282 of one of the second electrodes 281 and the upper surface 2581 of a corresponding one of the support features 258. The second region 273 extends downwardly from an edge of the first region 272, and is disposed between the second surrounding region 283 of one of the second electrodes 281 and the first surrounding region 2522 of a corresponding one of the first electrodes 252.

In some embodiments, the first region 272 is connected to and is in direct contact with the top region 282 of the one of the second electrodes 281 and the upper surface 2581 of the corresponding one of the support features 258. The second region 273 is connected to and is in direct contact with the second surrounding region 283 of the one of the second electrodes 281 and the first surrounding region 2522 of the corresponding one of the first electrodes 252. In some embodiments, the first region 272 is directly connected to the top surface 2523 of the corresponding one of the first electrodes 252.

FIG. 11 is a view illustrating the structure after the step for making the structure shown in FIG. 10. Referring to FIGS. 10 and 11, in sub-step 1027, the protective portion 254 and portions of the capacitance dielectric layer 27 and the layer 28 formed on the protective portion 254 are removed to expose the upper interconnect structure 240. After sub-step 1027, a plurality of the capacitors 29 are obtained, each of which includes one of the first electrodes 252, a corresponding one of the second electrodes 281, and a corresponding one of the capacitance dielectric portions 271. In some embodiments, as shown in FIG. 11, each of the capacitors 29 is in a pillar shape; while in other not shown embodiments, each of the capacitors 29 may be in a cylindrical shape. In some embodiments, each of the first electrodes 252 may serve as a bottom electrode of a corresponding one of the capacitors 29 and each of the second electrodes 281 may serve as a top electrode of the corresponding one of the capacitors 29. In some embodiments, for each of the capacitors 29, a ratio of a height (H) to a width (W) may range from about 1 to about 30, in some cases, from about 5 to about 30, and in some cases, from about 10 to about 30.

Referring to FIG. 1 and the example illustrated in FIG. 12, the method 100 proceeds to step 104, where a dielectric element 261 is formed over the structure shown in FIG. 11. Referring to FIG. 12, which is a view illustrating the structure after step 103, the dielectric element 261 is formed over the second electrodes 281 to fill the recess 246 (see FIG. 11). In some embodiments, the dielectric element 261 may be made of a dielectric material similar to those for forming the dielectric structure 238.

Referring to FIG. 1 and the example illustrated in FIG. 13, the method 100 proceeds to step 105, where a plurality of contact structures 262 are formed, thereby obtaining the semiconductor structure 20. Referring to FIG. 13, which is a view illustrating the structure after the structure shown in FIG. 12 is obtained, the contact structures 262 are formed in the dielectric element 261 to be electrically connected to the second electrodes 281 of the capacitors 29 and the upper interconnect structure 240. In some embodiments, the contact structures 262 may be made of an electrically conductive material similar to those for forming the via contacts 232.

In some embodiments, some steps in the method 100 may be modified, replaced, or eliminated without departure from the spirit and scope of the present disclosure.

For example, an additional step for forming a top plate 263 may be added in the method 100. Referring to FIG. 14, in some embodiments, after sub-step 1026 illustrated by FIG. 10, the top plate 263 may be formed over the second electrodes 281 to fill the recess 246 (see FIG. 10), where a portion of the top plate 263 is located between the capacitors 29 and the isolation feature 260. In some embodiments, the top plate 263 may be formed by depositing an electrically conductive material using PVD, CVD, ALD, other suitable techniques, or any combination thereof over the second electrodes 281, followed by removing an excess amount of the deposited material using dry etch, wet etch, chemical mechanical planarization (CMP), other suitable techniques, or any combination thereof. In some embodiments, the top plate 263 has a thickness (T4) above the dielectric structure 238, and the thickness (T4) ranges from about 10 nm to about 30 nm, and may be varied according to practical requirements. Possible materials for forming the top plate 263 may be similar to those for forming the second electrodes 281. In some embodiments, the top plate 263 may be made of an electrically conductive material the same as or different from that of the second electrodes 281.

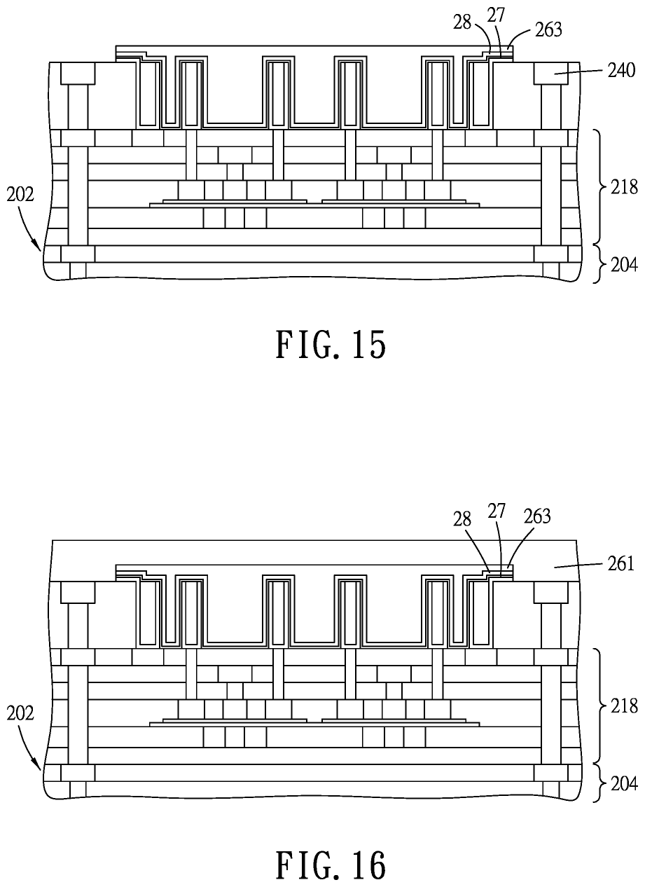

Referring to FIG. 15, after forming the top plate 263, the protective portion 254 and portions of the top plate 263, capacitance dielectric layer 27 and the layer 28 on the protective portion 254 (see also FIG. 14) are removed to expose the upper interconnect structure 240.

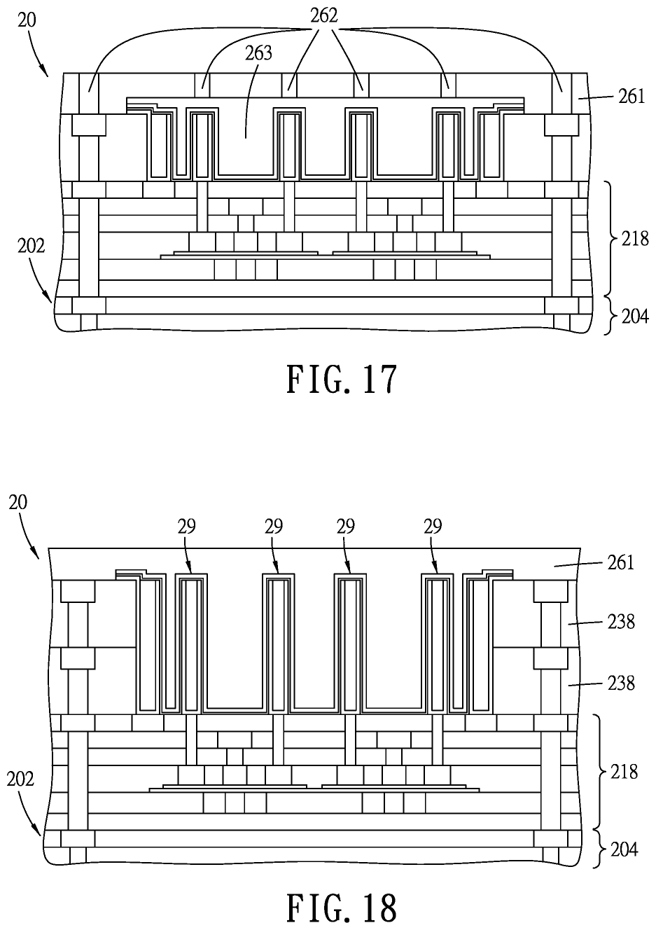

Then, referring to FIGS. 16 and 17, the dielectric element 261 and the contact structures 262 are formed in a manner similar to steps 104, 105 as described above so as to obtain the semiconductor structure 20. The semiconductor structure 20 shown in FIG. 17 is similar to that shown in FIG. 13 but further includes the top plate 263.

In some embodiments, a thickness of the dielectric structure 238 shown in FIG. 12 may be increased or the semiconductor structure 20 may include multiple dielectric structures 238 (see FIG. 18) so as to permit each of the capacitors 29 to have a height corresponding to a thickness of the dielectric structure 238 shown in FIG. 12 or corresponding to a total thickness of the multiple dielectric structures 238 shown in FIG. 18.

The isolation feature 260, in accordance with some embodiments of this disclosure, is made to surround the capacitors 29 so as to isolate the capacitors 29 from the upper interconnect structure 240, thereby alleviating interference (e.g., signal interference, etc.) between the memory devices (i.e., the capacitors 29 and the transistors 220) and the logic devices (i.e., the transistor features 206). In addition, the isolation feature 260 and the support features 258, in accordance with some embodiments of this disclosure, are simultaneously made, as described above with reference to FIG. 9, thereby simplifying process flow and improving production efficiency. In addition, each of the capacitors 29 is made to include the first electrode 252 surrounding a corresponding one of the support features 258, the second electrode 281 around the first electrode 252 and the corresponding support feature 258, and the capacitance dielectric portion 271 separating the first and second electrodes 252, 281, where the first electrode 252 may be conformally deposited in a narrow trench, followed by filling the trench with the corresponding support feature 258, and then forming the capacitance dielectric portion 271 thereover. In some embodiments, such structure allows each of the capacitors 29 to achieve a greater capacitance as compared to a concave capacitor. Moreover, the thickness or the number of the dielectric structure(s) 238 may be changed during manufacturing of the semiconductor structure 20 to adjust the capacitance of each of the capacitors 29.

In accordance with some embodiments of the present disclosure, a semiconductor structure includes a lower dielectric portion, a transistor, a support feature, and a capacitor. The transistor is formed in the lower dielectric portion, and includes a source electrode, a drain electrode, and a gate electrode. The support feature is disposed on the lower dielectric portion, and has an upper surface opposite to the lower dielectric portion, a lower surface confronting the lower dielectric portion, and a peripheral surface interconnecting the upper and lower surfaces. The capacitor includes a first electrode, a second electrode, and a capacitance dielectric portion. The first electrode includes a bottom region disposed beneath the lower surface of the support feature, and a first surrounding region extending upwardly from an edge of the bottom region to surround the peripheral surface of the support feature. The second electrode includes a top region disposed above the upper surface of the support feature, and a second surrounding region extending downwardly from an edge of the top region to surround the first surrounding region. The capacitance dielectric portion is disposed to isolate the first and second electrodes from each other.

In accordance with some embodiments of the present disclosure, the semiconductor structure further includes a bit line, and a via contact. The bit line is formed in the lower dielectric portion, and is electrically connected to one of the source and drain electrodes. The via contact extends downwardly from the bottom region of the first electrode into the lower dielectric portion so as to be electrically connected to the other one of the source and drain electrodes.

In accordance with some embodiments of the present disclosure, the lower surface of the support feature is connected to the bottom region of the first electrode. The upper surface of the support feature is connected to the capacitance dielectric portion.

In accordance with some embodiments of the present disclosure, the first surrounding region of the first electrode has a top surface which is flush with the upper surface of the support feature, and which is disposed underneath the top region of the second electrode.

In accordance with some embodiments of the present disclosure, the capacitance dielectric portion includes a first region disposed between the top region of the second electrode and the upper surface of the support feature, and a second region extending downwardly from an edge of the first region and disposed between the second surrounding region of the second electrode and the first surrounding region of the first electrode.

In accordance with some embodiments of the present disclosure, the first region of the capacitance dielectric portion is connected to the top region of the second electrode and the upper surface of the support feature. The second region of the capacitance dielectric portion is connected to the second surrounding region of the second electrode and the first surrounding region of the first electrode.

In accordance with some embodiments of the present disclosure, the first surrounding region of the first electrode has a top surface which is flush with the upper surface of the support feature, and which is connected to the first region of the capacitance dielectric portion.

In accordance with some embodiments of the present disclosure, the semiconductor structure further includes an isolation feature disposed on the lower dielectric portion and surrounding the capacitor and support feature.

In accordance with some embodiments of the present disclosure, the isolation feature includes a first surface opposite to the lower dielectric portion, and a second surface confronting the lower dielectric portion. The first surface of the isolation feature is flush with the upper surface of the support feature.

In accordance with some embodiments of the present disclosure, the semiconductor structure further includes a third electrode which surrounds the isolation feature.

In accordance with some embodiments of the present disclosure, a semiconductor structure includes a lower dielectric portion, a transistor, a via contact, a dielectric structure, a support feature, and a capacitor. The transistor is formed in the lower dielectric portion, and includes a source electrode, a drain electrode, and a gate electrode. The via contact is formed in the lower dielectric portion, and is electrically connected to one of the source and drain electrodes. The dielectric structure is disposed on the lower dielectric portion. The support feature is disposed in the dielectric structure. The capacitor is disposed in the dielectric structure, and includes a first electrode, a capacitance dielectric portion, and a second electrode. The first electrode is connected to the via contact, and surrounds the support feature. The capacitance dielectric portion surrounds the first electrode and is disposed on the support feature. The second electrode is disposed on the capacitance dielectric portion, and is isolated from the first electrode by the capacitance dielectric portion.

In accordance with some embodiments of the present disclosure, the semiconductor structure further includes an isolation feature which is disposed in the dielectric structure, which surrounds the capacitor, and which is disposed to separate the capacitor from the dielectric structure.

In accordance with some embodiments of the present disclosure, the semiconductor structure further includes a third electrode which surrounds the isolation feature. The first and third electrodes are made of the same material.

In accordance with some embodiments of the present disclosure, the support feature includes an upper surface opposite to the lower dielectric portion. The first electrode includes a top surface opposite to the lower dielectric portion. The isolation feature includes a first surface opposite to the lower dielectric portion. The upper surface of the support feature, the top surface of the first electrode, and the first surface of the isolation feature are flush with each other.

In accordance with some embodiments of the present disclosure, the semiconductor structure further includes a top plate which is disposed on the second electrode, a portion of the top plate is located between the capacitor and the isolation feature.

In accordance with some embodiments of the present disclosure, a method for manufacturing a semiconductor structure includes: forming a transistor in a lower dielectric portion; forming a dielectric structure which is disposed on the lower dielectric portion and which includes a plurality of spaced-apart openings; forming a plurality of first electrodes respectively in the openings; forming a plurality of support features respectively in the openings and on the first electrodes; forming a capacitance dielectric layer which includes a plurality of capacitance dielectric portions each covering one of the first electrodes and a corresponding one of the support features; and forming a layer including a plurality of second electrodes over the capacitance dielectric layer, the second electrodes being separated from the first electrodes through the capacitance dielectric portions, respectively.

In accordance with some embodiments of the present disclosure, the method further includes: prior to forming the first electrodes, forming a trench which is disposed in the dielectric structure and which surrounds the openings; during forming the first electrodes, a third electrode is simultaneously formed in the trench; and during forming the support features, an isolation feature is simultaneously formed in the trench over the third electrode.

In accordance with some embodiments of the present disclosure, forming the first electrodes includes: forming an electrode layer over the dielectric structure and in the openings and the trench; and removing portions of the electrode layer to form the first electrodes and the third electrode.

In accordance with some embodiments of the present disclosure, after removing portions of the electrode layer, a portion of the dielectric structure surrounded by the trench is removed to form a recess. Forming the capacitance dielectric layer is performed by forming the capacitance dielectric layer over the support features and the first electrodes which are exposed from the recess.

In accordance with some embodiments of the present disclosure, after forming the layer including the second electrodes, a top plate is formed over the second electrodes to fill the recess.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a lower dielectric portion;
a transistor formed in the lower dielectric portion, and including a source electrode, a drain electrode, and a gate electrode;
a support feature disposed on the lower dielectric portion, and having
an upper surface opposite to the lower dielectric portion,
a lower surface confronting the lower dielectric portion, and
a peripheral surface interconnecting the upper surface and the lower surface; and
a capacitor including
a first electrode including a bottom region disposed beneath the lower surface of the support feature, and a first surrounding region extending upwardly from an edge of the bottom region to surround the peripheral surface of the support feature,
a second electrode including a top region disposed above the upper surface of the support feature, and a second surrounding region extending downwardly from an edge of the top region to surround the first surrounding region, and
a capacitance dielectric portion disposed to isolate the first electrode and the second electrode from each other.

2. The semiconductor structure of claim 1, further comprising:
a bit line formed in the lower dielectric portion and electrically connected to one of the source electrode and the drain electrode; and
a via contact extending downwardly from the bottom region of the first electrode into the lower dielectric portion so as to be electrically connected to the other one of the source electrode and the drain electrode.

3. The semiconductor structure of claim 1, wherein:
the lower surface of the support feature is connected to the bottom region of the first electrode; and
the upper surface of the support feature is connected to the capacitance dielectric portion.

4. The semiconductor structure of claim 1, wherein the first surrounding region of the first electrode has a top surface which is flush with the upper surface of the support feature, and which is disposed underneath the top region of the second electrode.

5. The semiconductor structure of claim 1, wherein the capacitance dielectric portion includes a first region disposed between the top region of the second electrode and the upper surface of the support feature, and a second region extending downwardly from an edge of the first region and disposed between the second surrounding region of the second electrode and the first surrounding region of the first electrode.

6. The semiconductor structure of claim 5, wherein the first region of the capacitance dielectric portion is connected to the top region of the second electrode and the upper surface of the support feature, and the second region of the capacitance dielectric portion is connected to the second surrounding region of the second electrode and the first surrounding region of the first electrode.

7. The semiconductor structure of claim 6, wherein the first surrounding region of the first electrode has a top surface which is flush with the upper surface of the support feature, and which is connected to the first region of the capacitance dielectric portion.

8. The semiconductor structure of claim 1, further comprising an isolation feature disposed on the lower dielectric portion) and surrounding the capacitor (29) and support feature.

9. The semiconductor structure of claim 8, wherein:
the isolation feature includes a first surface opposite to the lower dielectric portion, and a second surface confronting the lower dielectric portion; and
the first surface of the isolation feature is flush with the upper surface of the support feature.

10. The semiconductor structure of claim 8, further comprising a third electrode which surrounds the isolation feature.

11. A semiconductor structure comprising:
a lower dielectric portion;
a transistor formed in the lower dielectric portion, and including a source electrode, a drain electrode, and a gate electrode;
a via contact formed in the lower dielectric portion and electrically connected to one of the source electrode and the drain electrode;
a dielectric structure disposed on the lower dielectric portion;
a support feature disposed in the dielectric structure; and
a capacitor disposed in the dielectric structure, and including
a first electrode which is connected to the via contact and which surrounds the support feature,
a capacitance dielectric portion which surrounds the first electrode and which is disposed on the support feature, and
a second electrode which is disposed on the capacitance dielectric portion and which is isolated from the first electrode by the capacitance dielectric portion.

12. The semiconductor structure of claim 11, further comprising an isolation feature which is disposed in the dielectric structure, which surrounds the capacitor, and which is disposed to separate the capacitor from the dielectric structure. 13 The semiconductor structure of claim 12, further comprising a third electrode which surrounds the isolation feature, the first electrode and the third electrode being made of the same material. 14 The semiconductor structure of claim 13, wherein:
the support feature includes an upper surface opposite to the lower dielectric portion;
the first electrode includes a top surface opposite to the lower dielectric portion;
the isolation feature includes a first surface opposite to the lower dielectric portion; and
the upper surface of the support feature, the top surface of the first electrode, and the first surface of the isolation feature are flush with each other.

15. The semiconductor structure of claim 12, further comprising a top plate which is disposed on the second electrode, a portion of the top plate being located between the capacitor and the isolation feature.

16. A method for manufacturing a semiconductor structure, comprising:
forming a transistor in a lower dielectric portion;
forming a dielectric structure which is disposed on the lower dielectric portion and which includes a plurality of spaced-apart openings;
forming a plurality of first electrodes respectively in the openings;
forming a plurality of support features respectively in the openings and on the first electrodes;
forming a capacitance dielectric layer which includes a plurality of capacitance dielectric portions each covering one of the first electrodes and a corresponding one of the support features; and
forming a layer including a plurality of second electrodes over the capacitance dielectric layer, the second electrodes being separated from the first electrodes through the capacitance dielectric portions, respectively.

17. The method of claim 16, further comprising:
prior to forming the first electrodes, forming a trench which is disposed in the dielectric structure and which surrounds the openings;
during forming the first electrodes, a third electrode is simultaneously formed in the trench; and
during forming the support features, an isolation feature is simultaneously formed in the trench over the third electrode.

18. The method of claim 17, wherein, forming the first electrodes includes:
forming an electrode layer over the dielectric structure and in the openings and the trench; and
removing portions of the electrode layer to form the first electrodes and the third electrode.

19. The method of claim 18, wherein:
after removing portions of the electrode layer, a portion of the dielectric structure surrounded by the trench is removed to form a recess; and
forming the capacitance dielectric layer is performed by forming the capacitance dielectric layer over the support features and the first electrodes which are exposed from the recess.

20. The method of claim 19, wherein, after forming the layer including the second electrodes, a top plate is formed over the second electrodes to fill the recess.
